(19) United States
(12) Patent Application Publication
(10) Pub. No.: US 2004/0100764 A1
(43) Pub. Date: May 27, 2004

(54) Internally damped drive CRU mounting system for storage subsystems

(76) Inventors: George E. Hanson, Andover, KS (US); Sean G. 'Winter, Wichita, KS (US)

Correspondence Address: LSI Logic Corporation, Corporate Legal Department, Intellectual Property Services Group, 1551 McCarthy Boulevard, M/S D-106, Milpitas, CA, 95035, US

(21) Appl. No.: 10/301,388

(22) Filed: Nov. 21, 2002

(51) Int. Cl. H05K 7/12

(52) U.S. Cl. 361/686

(57) ABSTRACT

A spring for mounting a computer customer replaceable unit (CRU) is provided. The spring comprises a laminated sandwich material that includes three layers: a first outer layer of metal, a second middle layer of polymeric material, and a third outer layer of metal. The spring is attached to the CRU and retains the CRU within a computer system chassis, and the spring dissipates vibration energy through fluid friction within the second layer. The fluid friction within the second layer can be the result of either opposing lateral movement of the first and third layers due to vibration, or different mode shapes of the first and third layers due to vibration.

### BACKGROUND OF THE INVENTION

1. Technical Field

The present invention is directed generally toward customer replaceable units (CRUs), and more specifically, how CRUs are mounted into subsystems.

2. Description of the Related Art

Controller modules and drive trays are modular computer components that are usually connected together in a customer-specified configuration to produce storage systems. Controller modules function as the interface between a host system and the drive tray array. The drive trays use enclosure service modules (ESMs) as the interconnection to the drives contained within a drive tray. The ESMs also perform diagnostic monitor functions for the drive array.

ESMs may take the form of customer replaceable units (CRUs), which make up subsystems within a storage system. This provides the customer with more freedom and direct control over the configuration and maintenance of the subsystems. The CRUs contain insertion/extraction levers that are used to install and remove CRUs from a storage system chassis. Conventionally, drives are mounted into die cast shells that have plastic extraction and insertion levers mounted on their accessible surfaces. The CRUs are then slid past guides into or out of the main chassis of the drive tray until the connectors on the drives match up and mate with the connectors on the chassis midplane.

Leaf springs are installed on CRUs. The leaf springs are formed and stamped in a hard tool and are screwed into place. They deflect substantially as the CRU is installed and assist in the retention and positioning of the drives in the assembly. The stated purpose for these leaf springs is to reduce vibration. The concept of rotational vibration is an important issue with drive-based system designs. Rotational vibration is the direct result of eccentric mass rotation. It could be a phenomenon observable in any motor based system. In order to quantify the magnitude of this phenomenon, a Rotational Vibration Index (RVI) was defined by one of the larger drive manufacturers. In practice an RVI number is developed for an enclosure by performing an accelerometry study of that enclosure. The goal of system designers is to reduce that RVI number to an acceptable level. Since high rotational vibrations have a detrimental effect upon data fidelity, it is often most expedient to reduce the Rotational Vibration Index (RVI) as much as possible.

The leaf springs are sometimes referred to as electromagnetic interference (EMI) reduction springs because of their tendency to enforce a good chassis-to-chassis ground connection, sealing up gaps and thus reducing the prevalence of EMI.

Springs absorb and release energy but are not particularly good at dissipating energy.

They are usually designed to efficiently store and release energy. When springs release stored energy as they return to their undeformed shape, they introduce that energy back into the system. It is the dissipation of vibrational energy that is important here, since that vibrational energy might cause the heads of a drive affected by that energy to misread a track. However, springs are only one category of mechanical components that contribute to the vibrational response of any mechanical assembly. The other two categories are masses and dampers.

Masses absorb energy and then express the absorption of that energy in the form of increased velocity. Masses store energy in its kinetic form, in contrast to springs, which store energy in its potential form. As the masses within a system increase in magnitude, the vibrational natural frequencies of the mechanical system tend to decrease routinely. Increasing the mass of a system reduces the impact of vibration when the vibrational energy within a system is limited.

However, neither masses nor springs dissipate energy well. Dampers dissipate energy by the existence of relative motion between internal components within themselves. This internal motion, within dampers, is generally transverse to the axis of applied force. Thus, for example, as an elastomer regains its original shape, the restoring motion is off-axis. This dissipates kinetic energy through friction and heat.

Some drive manufacturers have, historically, included masses and dampers within their products. However, current trends in drive manufacturing point toward reduced use of integral masses and dampers as component space in these products declines.

Therefore, in light of reduced inclusion of dampers in drive CRU manufacture, it would be desirable to have an alternate method for reducing vibrational disturbances to drive CRUs.

### SUMMARY OF THE INVENTION

The present invention provides a spring for mounting a computer customer replaceable unit (CRU). The spring comprises a laminated sandwich material that includes three layers: a first outer layer of metal, a second middle layer of polymeric material, and a third outer layer of metal. The spring is attached to the CRU and retains the CRU within a computer system chassis, and the spring dissipates vibration energy through fluid friction within the second layer. The fluid friction within the second layer can be the result of either opposing lateral movement of the first and third layers due to vibration, or different mode shapes of the first and third layers due to vibration.

Additional embodiments use more complex material configurations, including multiple interlaminated layers of metals and elastomeric components. For example, metallic layers of differing composition may be used. In addition, the present invention may use layers constructed of composite materials that include carbon and glass fibre. These materials are naturally less resonant than metals, since they tend to be the mechanical assembly of very strong fibrous components supported by polymeric matrix materials. The softer matrix materials, being polymeric, are potentially more dissipative of vibrational energy. Such composite materials are also orientation specific and desirable axis specific properties may be exploitable in the design of these laminated spring assemblies.

### BRIEF DESCRIPTION OF THE DRAWINGS

The novel features believed characteristic of the invention are set forth in the appended claims. The invention itself however, as well as a preferred mode of use, further objects and advantages thereof, will best be understood by reference to the following detailed description of an illustrative embodiment when read in conjunction with the accompanying drawings, wherein:

FIGS. 1A and 1B depict diagrams illustrating a CRU leaf spring in accordance with the prior art;

FIG. 2 depicts a diagram illustrating a leaf spring composed of laminated sandwich materials in accordance with the present invention;

FIG. 3 depicts a diagram illustrating the dissipation of energy through shear in the binding layer in accordance with the present invention; and

FIG. 4 depicts a diagram illustrating the dissipation of energy through pumping action in the binding layer in accordance with the present invention.

### DETAILED DESCRIPTION

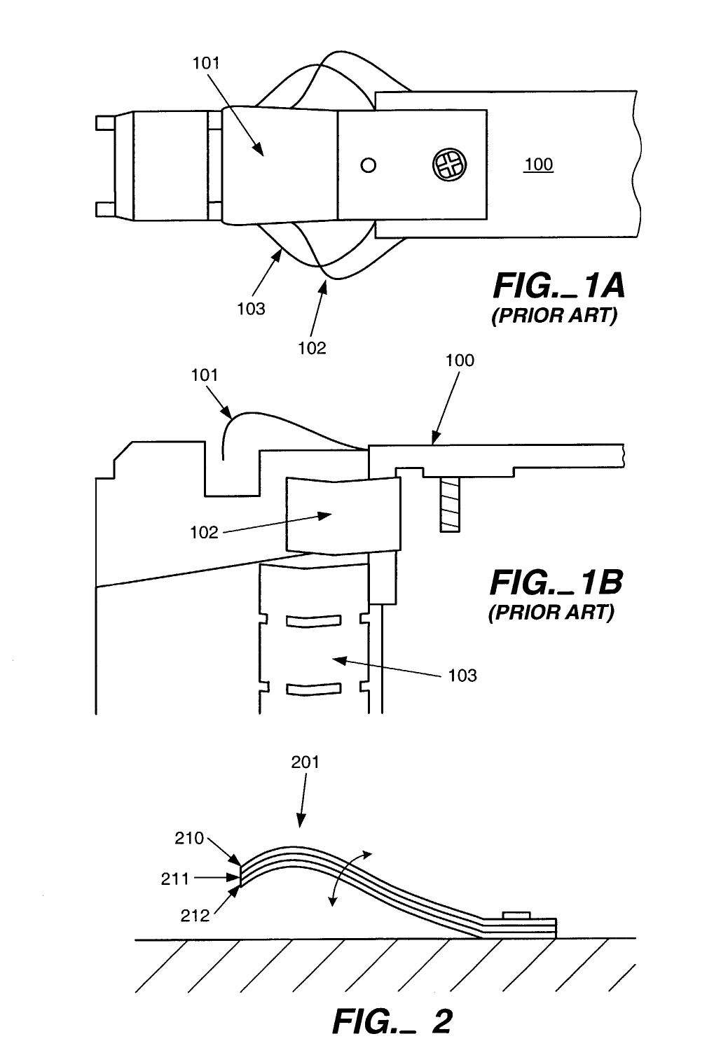

Referring to FIGS. 1A and 1B, diagrams illustrating a CRU leaf spring are depicted in accordance with the prior art. FIG. 1A illustrates the top view of leaf springs 101, 102 and 103 attached to a drive CRU 100. FIG. 1B illustrates a side view of the springs 101-103 and CRU 100. The leaf springs 101-103 are formed and stamped in a hard tool and then screwed into place. The springs 101-103 deflect substantially as the CRU 100 is installed and assist in the retention of the drive in the assembly. The main goal of the leaf springs 101-103 is to reduce vibration. However, the springs 101-103 absorbs and releases energy but is not particularly good at dissipating energy. Their ability to dissipate energy is limited to frictional losses in contact regions. When the springs 101-103 release stored energy as they return to their undeformed shape, they introduce energy back into the system. It is the dissipation of vibrational energy that is important here, since the vibrational energy might cause the heads of the drive to misread a track.

The present invention may be implemented in a leaf spring structure similar to that depicted in FIG. 1, but using different materials that facilitate the dissipation of vibrational energy.

Referring to FIG. 2, a diagram illustrating a leaf spring composed of laminated sandwich materials is depicted in accordance with the present invention. Special composites can be used to reduce vibrational effects in drive CRUs. These composites generally include a low glass temperature polymer that acts as an elastomer. The polymer flexes and flows under vibrational stress. This viscous flow stirs the polymer, and fluid friction dissipates energy in the system, which reduces vibration amplitudes and decreases the impact of the residual vibrational energy within the system.

The present invention uses a sandwich material composed of two sheets of metal held together by a sheet of polymeric adhesive. This material deadens vibrations in two ways that both depend on fluid friction. The first means of dissipating energy occurs when the two sheets move laterally with respect to each other, which causes shear in the elastomeric binder. The other means of dissipating energy is more complex. The components of the sandwich have slightly different natural frequencies that result in different mode shapes. If the two metallic sheets attempt to take on differing mode shapes, the binder material is pumped back and forth, dissipating energy by fluid friction.

In FIG. 2, the spring 201 is used to retain and support drive CRUs in the chassis of the drive tray, similar to the prior art leaf springs. The spring is constructed from three layers 210, 211, and 212 of sandwich materials. Because the spring is constructed from the sandwich materials, it can effectively dissipate unusually high levels of energy via viscous damping in the inner binder layer 211. The spring profile may remain the same as standard leaf springs such as spring 101. To achieve spring constants similar to prior art springs, the laminate material for the outer layers 210 and 212 is metal, but thinner than that used in the prior art. The inner binding layer 211 can be made from, e.g., PSA adhesive, as well as similar viscous compounds. The spring 201 in the present invention can be manufactured using the same hard tools as those used for conventional springs.

Many types of polymeric materials can be used for the middle layer 211 of the spring 201. When polymeric materials are squeezed, they flex and flow in directions perpendicular to the application of force. It is this perpendicular flow that dissipates energy. Motion of the “fluid” material perpendicular to the mechanical axis of motion is not efficiently coupled back into that mechanical motion, thus producing a loss of vibrational energy. The materials of choice for the inner layer 211 include non-hardening adhesives (e.g., PSA), natural and synthetic rubbers, polymer solutions (e.g., plasticized PVC), room temperature vulcanizing silicones, low melting point plastics, etc.

The metallic components that make up the outer layers 210 and 212 of the spring 201 can include hard (Martensitic) stainless steels, high carbon steels, beryllium copper alloys and other types of stiff brass, phosphor bronze, etc.

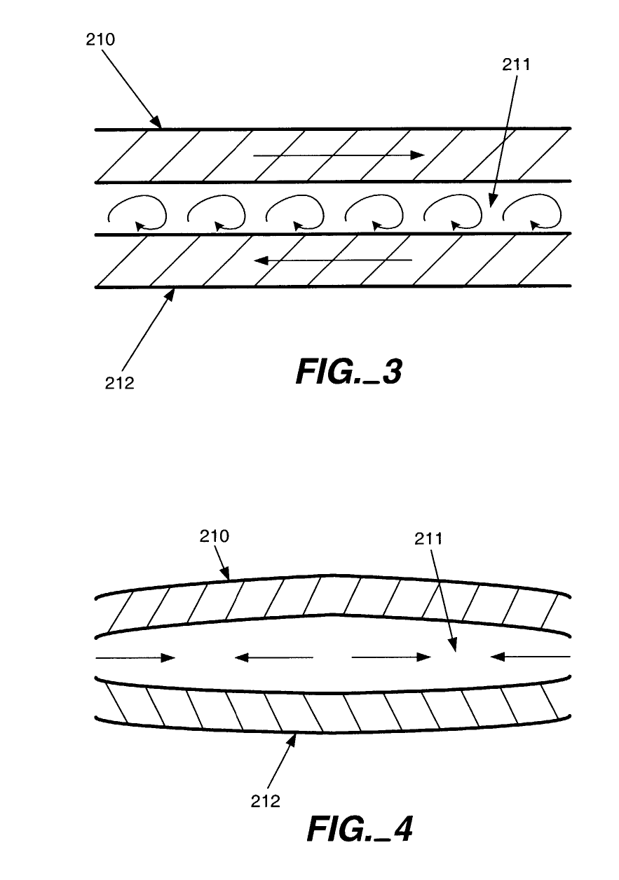

Referring to FIG. 3, a diagram illustrating the dissipation of energy through shear in the binding layer is depicted in accordance with the present invention. FIG. 3 shows a close up view of a section of the laminated sandwich materials used to construct the leaf spring 201 in FIG. 2. In this figure, vibrations cause the outer layers 210 and 312 to slide in opposite directions, as indicated by the arrows in these layers. As a result of the counter movement of the outer layers 210 and 212, the inner viscous layer 211 experiences shear forces, indicated by the curving arrows. The shear forces create friction within the inner layer 211, which dissipates kinetic energy in the form of heat. This dissipation reduces the amount of energy that can be returned to the assembly in the form of mechanical vibrations of the leaf spring 201.

Referring to FIG. 4, a diagram illustrating the dissipation of energy through pumping action in the binding layer is depicted in accordance with the present invention. Similar to FIG. 3, FIG. 4 shows a close up view of a section of the laminated sandwich materials used to construct the leaf spring 201 in FIG. 2. In this example, vibration causes the outer layers 210 and 212 to assume different mode shapes, in which the outer layers 210 and 212 buckle in opposite directions from each other. This buckling action of the out layers 210 and 212 causes a back and forth pumping action, indicated by the arrows in the middle layer 212. Similar to the shearing action in FIG. 3, the pumping action dissipates kinetic energy as heat, thus reducing mechanical energy returned to the assembly from the spring 201.

In one embodiment of the present invention, the two outer layers 210 and 212 of the spring 201 are composed of dissimilar metals. The different respective stiffness of the metals ensures differing mode shapes under vibrational strain. Another method to ensure differing mode shapes is to use the same metal for both outer layers 210 and 212, but use a different thickness for each one. Both methods (different metals and different thickness) may be used in combination, depending on the needs of the designer.

It should be pointed out that the shearing and pumping actions illustrated in FIGS. 3 and 4 respectively can occur simultaneously in the sandwich material, thereby dissipating energy via two different friction mechanisms, as mentioned briefly above.

An advantage of the present invention is the ability of the springs to include the damping function at no space penalty. The new springs take up the same amount of space as the prior art springs and perform the same basic functions, but with the addition of the new damping properties. The damping effect of the new spring design is multiplied by the number of such springs in the system. Each spring provides a bi-directional barrier that prevents vibration from the drive from being propagated into the system and vibrations from the system from being propagated into the drive.

The description of the preferred embodiment of the present invention has been presented for purposes of illustration and description, but is not intended to be exhaustive or limited to the invention in the form disclosed. Many modifications and variations will be apparent to those of ordinary skill in the art. The embodiment was chosen and described in order to best explain the principles of the invention the practical application to enable others of ordinary skill in the art to understand the invention for various embodiments with various modifications as are suited to the particular use contemplated.

What is claimed is:

1. A spring for mounting a computer customer replaceable unit (CRU), the spring comprising:
a first outer layer of metal;
a second middle layer of polymeric material;
a third outer layer of metal;
wherein the spring is attached to the CRU and retains the CRU within a computer system chassis; and
wherein the spring dissipates vibration energy through fluid friction within the second layer.

2. The spring according to claim 1, wherein the fluid friction within the second layer is caused by opposing lateral movement of the first and third layers due to vibration.

3. The spring according to claim 1, wherein the fluid friction within the second layer is caused by different mode shapes of the first and third layers due to vibration.

4. The spring according to claim 1, wherein the first and third layers are made of steel.

5. The spring according to claim 4, wherein the first and third layers are made of Martensitic stainless steel.

6. The spring according to claim 4, wherein the first and third layers are made of high carbon steel.

7. The spring according to claim 1, wherein the first and third layers are made of stiff brass.

8. The spring according to claim 7, wherein the first and third layers are made of a beryllium copper alloy.

9. The spring according to claim 1, wherein the first and third layers are made of different metals.

10. The spring according to claim 1, wherein the first and third layers are of different thickness.

11. The spring according to claim 1, wherein the second layer is made of a non-hardening adhesive.

12. The spring according to claim 11, wherein the second layer is made of PSA adhesive.

13. The spring according to claim 1, wherein the second layer is made of rubber.

14. The spring according to claim 1, wherein the second layer is made of plasticized PVC.

15. The spring according to claim 1, wherein the second layer is made of room temperature vulcanizing silicone.
